(19) United States
(12) Patent Application Publication
(10) Pub. No.: US 2026/0353793 A1
(43) Pub. Date: Nov. 5, 2026

(54) METHOD AND STRUCTURE FOR HYBRID CELL CONFIGURATION IN SEMICONDUCTOR DEVICES

(71) Applicant: Taiwan Semiconductor Manufacturing Co., Ltd., Hsinchu (TW)

(72) Inventors: Zhi-Chang Lin, Zhubei City (TW); Tsung-Kai Chiu, Hsinchu (TW)

(21) Appl. No.: 19/739,330

(22) Filed: Jul. 13, 2026

Related U.S. Application Data
(63) Continuation of application No. 18/973,379, filed on Dec. 9, 2024.
(60) Provisional application No. 63/695,147, filed on Sep. 16, 2024.

(51) Int. Cl. H10D 84/85; H10D 84/01

(52) U.S. Cl. CPC H10D 84/856; H10D 84/0167; H10D 84/017; H10D 84/0188; H10D 84/851

(57) ABSTRACT

In an embodiment, a method includes a semiconductor device including a first cell including a first active region and a second active region adjacent to the first active region, where each of the first active region and the second active region includes a first nanostructure extending between first source/drain regions, and a second nanostructure over the first nanostructure, the second nanostructure extending between second source/drain regions, and a first gate stack around the first nanostructure of the first active region and the first nanostructure of the second active region, and a second gate stack over the first gate stack and disposed around the second nanostructure of the first active region and the second nanostructure of the second active region.

### CROSS-REFERENCE TO RELATED APPLICATIONS

This application is a continuation of U.S. Patent Application No. 18/973,379 filed on Dec. 9, 2024, which application claims priority to U.S. Application No. 63/695,147, filed on Sep. 16, 2024, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a stacked transistor, such as a complementary field-effect transistor (CFET), in a three-dimensional view, in accordance with some embodiments.

FIGS. 2-12C are views of intermediate stages in the manufacturing of CFETs for system-on-chip (SOC) cells and high-performance computing (HPC) cells, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor device may be formed that includes a plurality of system-on-chip (SOC) cells and a plurality of high-performance computing (HPC) cells that are formed in a single wafer. For example, the plurality of SOC cells may be formed in a first region of the wafer and the plurality of HPC cells may be formed in a second region of the wafer. Each SOC cell and HPC cell may comprise complementary field-effect transistors (CFETs). A CFET includes a lower nanostructure-FET and an upper nanostructure-FET disposed over the lower nanostructure-FET. The semiconductor device may be formed by first forming channel layers and dummy layers alternatingly over a substrate to form a multi-layer stack. The multi-layer stack may be then patterned to form first fin structures in a first region for corresponding SOC cells, and second fin structures in a second region for corresponding HPC cells. Each first fin structure may comprise first dummy nanostructures and first channel nanostructures formed from the dummy layers and the channel layers, respectively. The first channel nanostructures of each first fin structure may form part of a first active region of a subsequently formed SOC cell. The channel layers of each second fin structure may form part of a subsequently formed HPC cell, wherein first trenches are disposed between adjacent second fin structures. A width of each first fin structure is smaller than a width of each second fin structure. After the first fin structures and the second fin structures are formed, each second fin structure is patterned further to form a pair of third fin structures that are disposed on opposite sides of a second trench. The width of each first fin structure is smaller than a width of each third fin structure, and a width of each first trench is greater than a width of each second trench. Each third fin structure of the pair of third fin structures may comprise second dummy nanostructures and second channel nanostructures formed from the dummy layers and the channel layers, respectively, wherein the second channel nanostructures of each third fin structure of the pair of third fin structures may form part of a second active region of a subsequently formed HPC cell. The HPC cell may therefore comprise two second active regions.

Advantageous features of one or more embodiments disclosed herein may allow for the integration of both system-on-chip (SOC) cells and high-performance computing (HPC) cells on a single wafer (e.g., using a hybrid cell configuration). As a result, device performance can be optimized for different application needs. In addition, the further patterning of each second fin structure to form the pair of third fin structures that are disposed on opposite sides of the second trench, wherein the width of each first fin structure is smaller than the width of each third fin structure enables a larger effective width of the second active regions of the subsequently formed HPC cell. This may result in enhanced device performance that is suitable for high-performance computing tasks. Further, the formation of the second trench may allow for an improved removal (e.g., having less material residues) of the second dummy nanostructures from the third fin structures during a subsequent etching process, as well as a reduction in the amount of sub-threshold swing degradation of the subsequently formed CFETs, while still maintaining the benefits of the larger effective widths of the second active regions. In addition, a need for challenging multi-sheet channel epitaxy processes is eliminated by avoiding multi-sheet channel formation. As a result, the manufacturing process is simplified and yield improvements can be achieved.

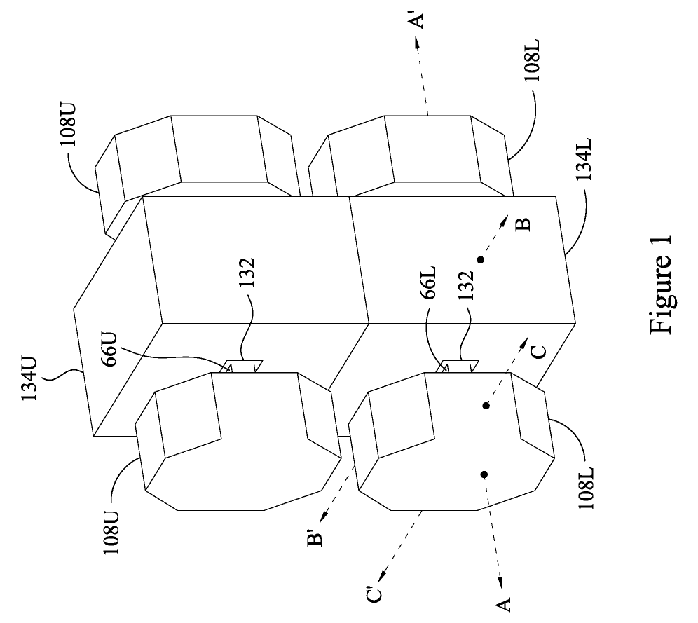

FIG. 1 illustrates an example schematic of a stacked transistor, such as a complementary field-effect transistor (CFET), in accordance with some embodiments. FIG. 1 is a three-dimensional view, where some features of the CFETs are omitted for illustration clarity.

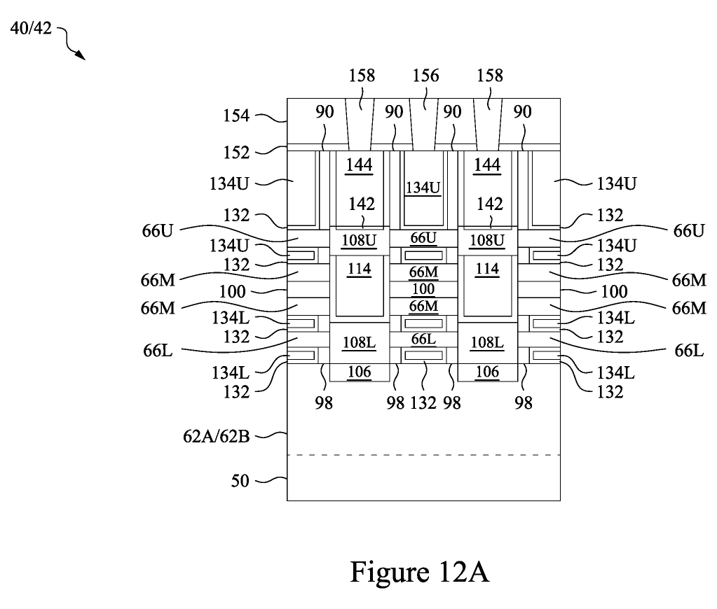

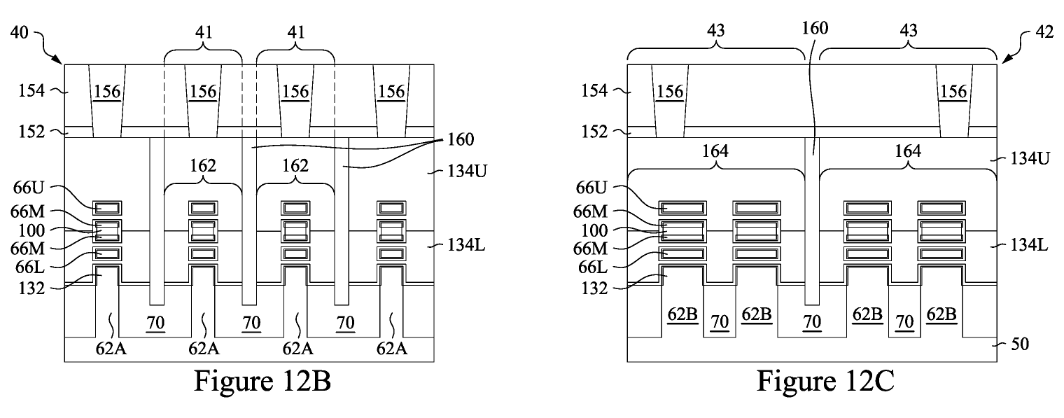

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1, see FIGS. 12A-12C) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U. Alternatively, a lower gate electrode 134L may be coupled to an upper gate electrode 134U. Further, the upper epitaxial source/drain regions 108U may be separated from lower epitaxial source/drain regions 108L by one or more dielectric layers (not explicitly illustrated in FIG. 1, see FIGS. 12A-12C). The isolation features between channel regions, gates, and source/drain regions allow for vertically stacked transistors, thereby improving device density. Because of the vertically stacked nature of CFETs, the schematic may also be referred to as stacked transistors or folding transistors.

FIG. 1 further illustrates reference cross-sections that are used in later figures. Cross-section A-A' is parallel to a longitudinal axis of the semiconductor nanostructures 66 of a CFET and in a direction of, for example, a current flow between the source/drain regions 108 of the CFET. Cross-section B-B' is perpendicular to cross-section A-A' and along a longitudinal axis of a gate electrode 134 of a CFET. Cross-section C-C' is parallel to cross-section B-B' and extends through the source/drain regions 108 of the CFETs. Subsequent figures refer to these reference cross-sections for clarity.

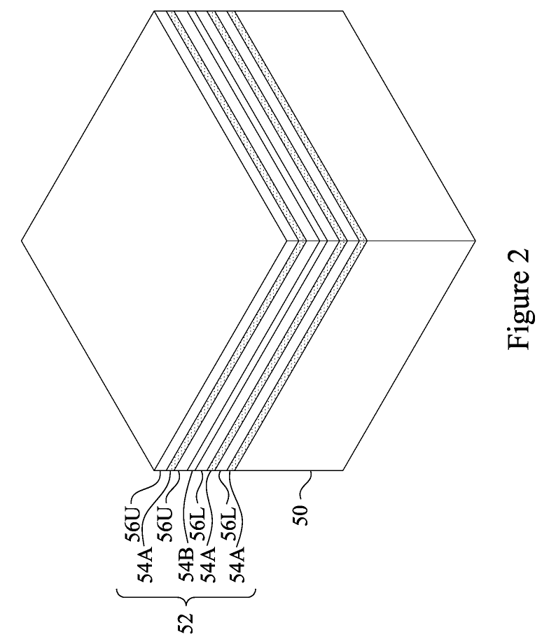

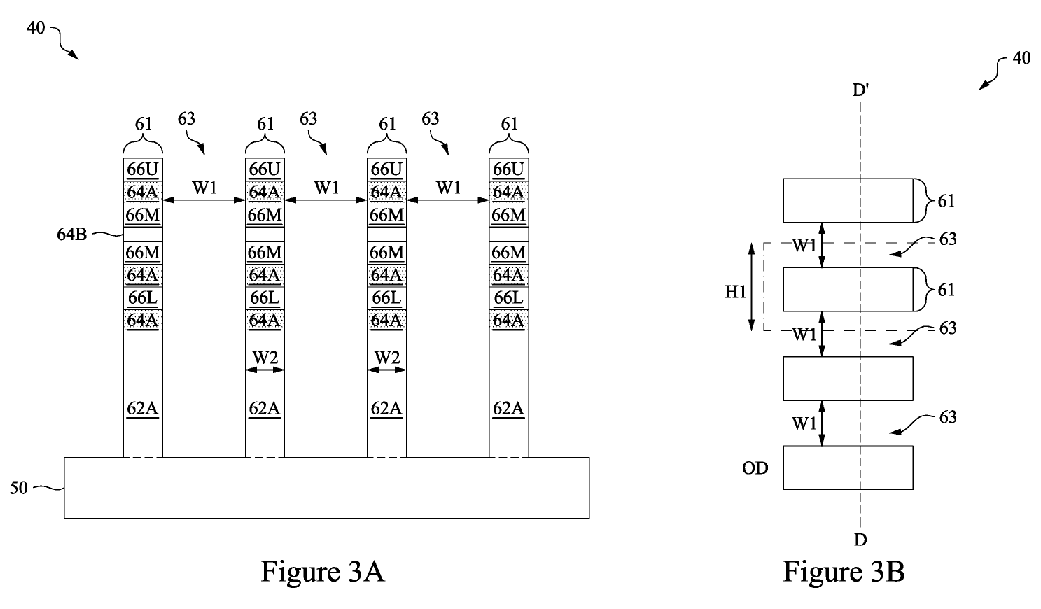

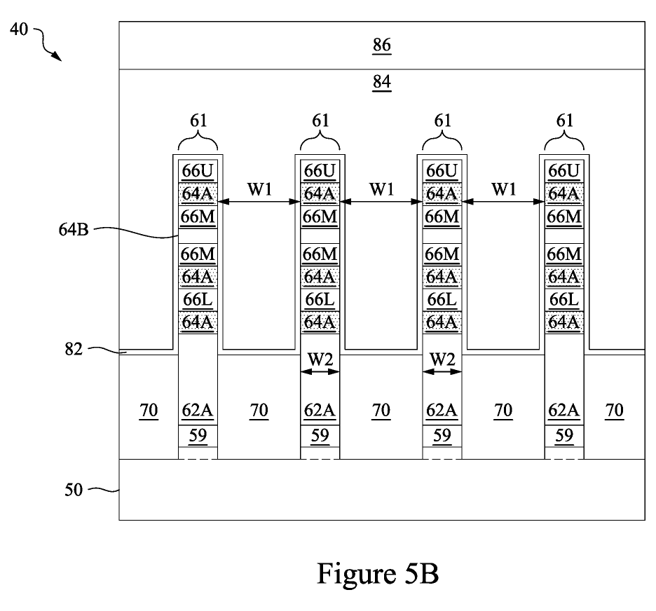

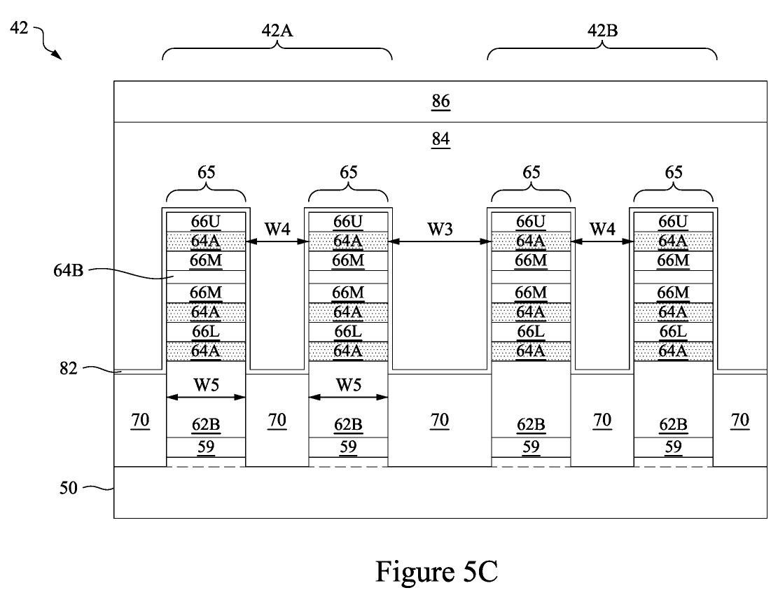

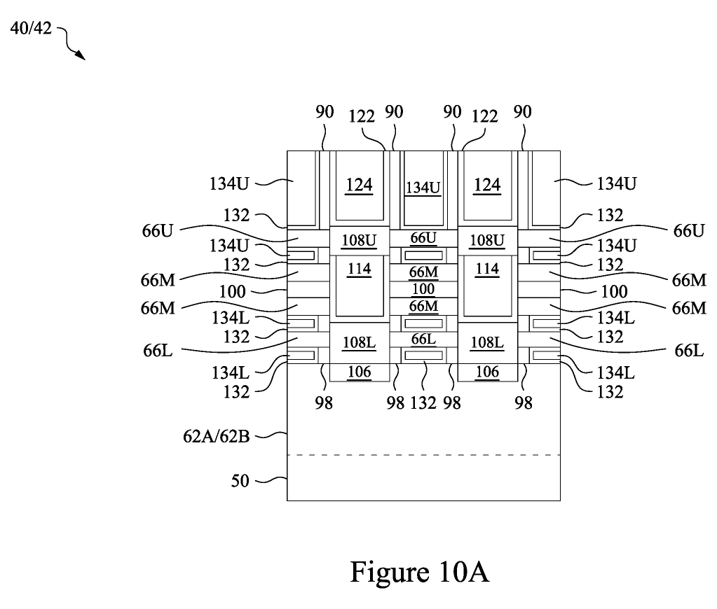

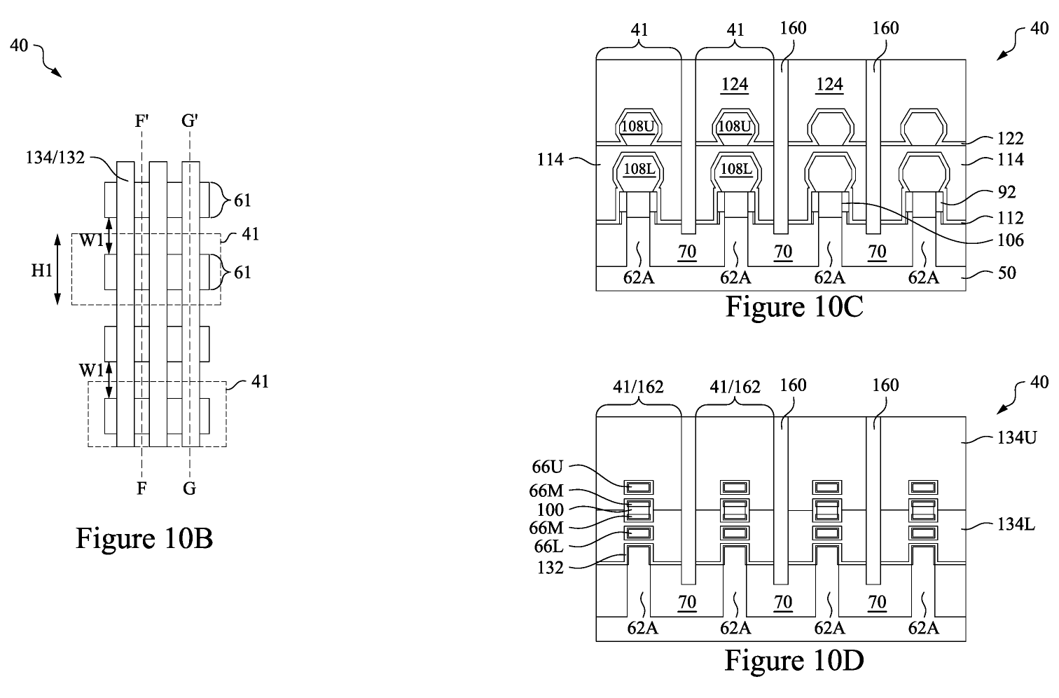

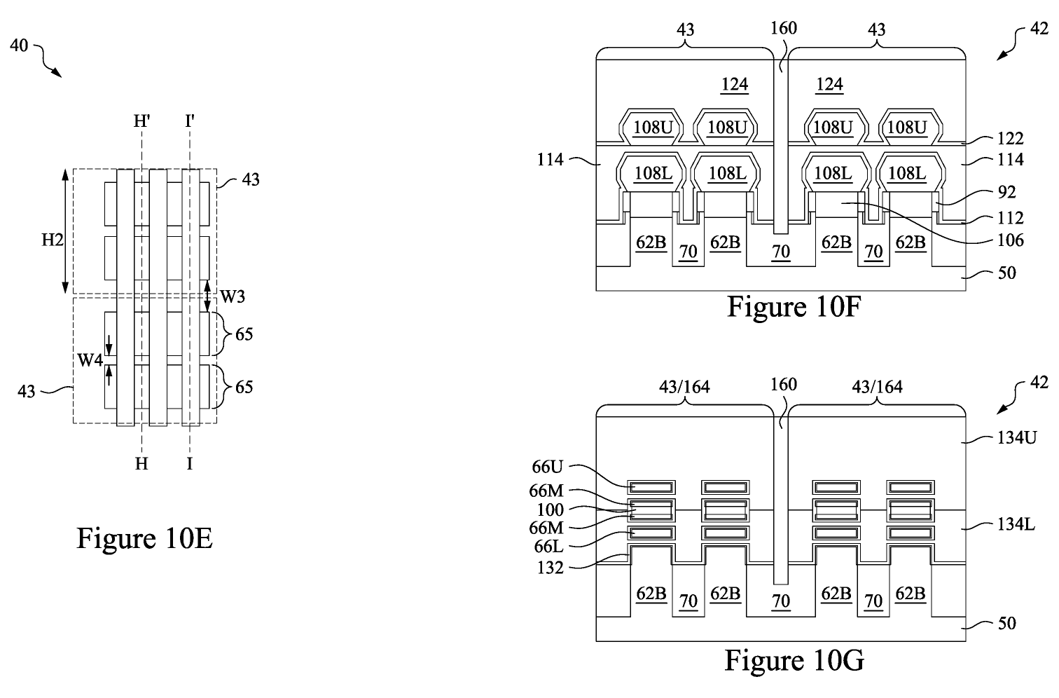

FIGS. 2-12C are views of intermediate stages in the manufacturing of CFETs for SOC cells and HPC cells, in accordance with some embodiments. FIG. 2 is a three-dimensional view showing a similar three-dimensional view as FIG. 1. FIGS. 5A, 6, 7, 8, 9, 10A, 11 and 12A illustrate cross-sectional views along a similar cross-section as reference cross-section A-A' in FIG. 1. FIGS. 3A, 4A, 5B, 5C, 10D and 10G, illustrates cross-sectional views along a similar cross-section as reference cross-section B-B' in FIG. 1. FIGS. 10C and 10F illustrate cross-sectional views along a similar cross-section as reference cross-section C-C' in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including a specific number of the dummy layers 54 and a specific number of the semiconductor layers 56. It should be appreciated that the multi-layer stack 52 may include any number of the dummy layers 54 and the semiconductor layers 56. In an embodiment, the semiconductor layers 56 may include two lower semiconductor layers 56L and two upper semiconductor layers 56U as shown in FIG. 2. In an embodiment, the dummy layers 54 may include one first dummy layer 54A disposed above the second dummy layer 54B, and two first dummy layers 54A disposed below the second dummy layer 54B. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A and the second dummy layer 54B may be formed of a first semiconductor material. The first semiconductor material may be selected from the candidate semiconductor materials of the substrate 50. In some embodiments, the dummy layers 54 (e.g., the first dummy layers 54A and the second dummy layer 54B) are formed of or comprise silicon germanium, and the second dummy layer 54B may be formed of germanium or silicon germanium with a higher germanium atomic percentage than the first dummy layers 54A. The first dummy layers 54A and the second dummy layer 54B have a high etching selectivity to one another, such that the second dummy layer 54B may be removed at a faster rate than the first dummy layers 54A in subsequent processing. The semiconductor layers 56 (including the lower semiconductor layers 56L and upper semiconductor layers 56U) are formed of a second semiconductor material that is different from the first semiconductor material. The second semiconductor material may be selected from the candidate semiconductor materials of the substrate 50. In some embodiments, the semiconductor layers 56 are formed of silicon. The semiconductor layers 56 and the dummy layers 54 have a high etching selectivity to one another, such that the dummy layers 54 (e.g., the first dummy layers 54A and the second dummy layer 54B) may be removed at a faster rate than the semiconductor layers 56 (e.g., the lower semiconductor layers 56L and the upper semiconductor layers 56U) in subsequent processing.

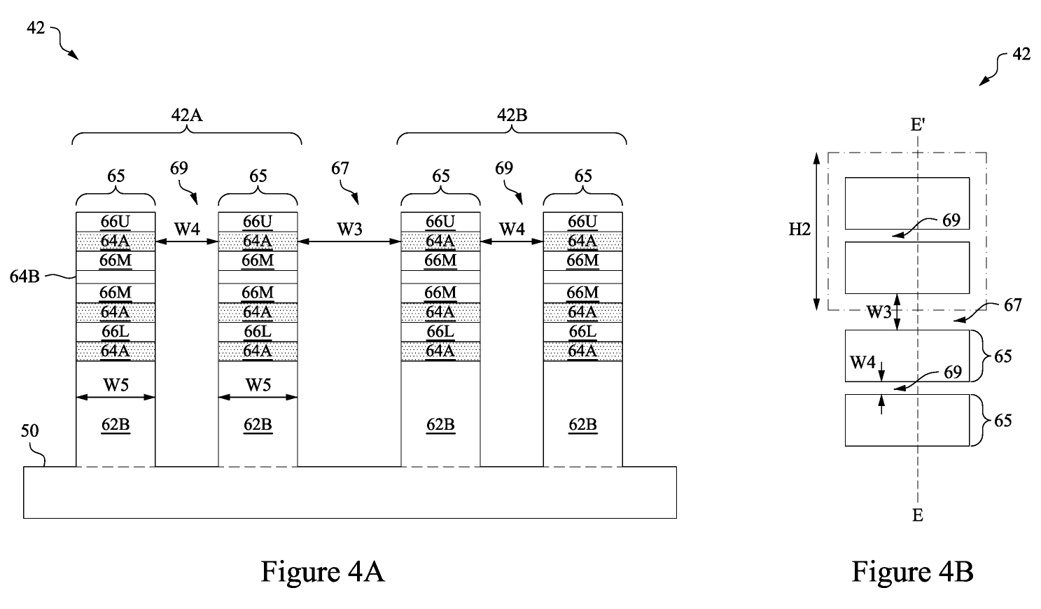

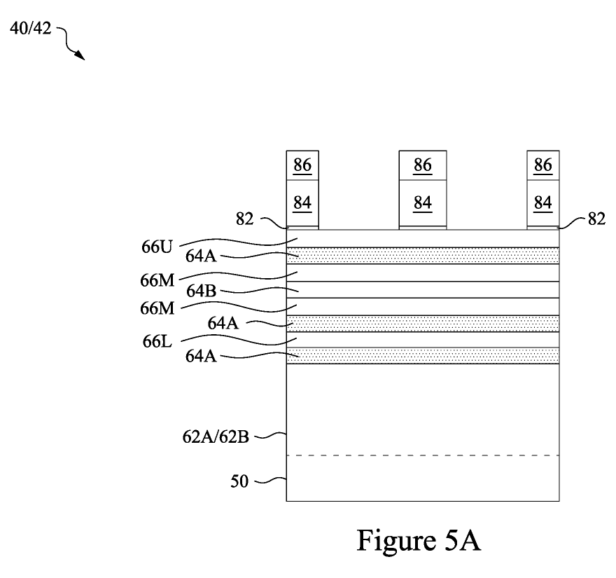

FIGS. 3A-4B illustrate the formation of fin structures 61 and fin structures 65 in the substrate 50. For example, FIGS. 3A-3B illustrate the formation of the fin structures 61 in a first region 40 of the substrate 50, and FIGS. 4A-4B illustrate the formation of the fin structures 65 in a second region 42 of the substrate 50. The first region 40 and the second region 42 may be located anywhere on the substrate 50. The first region 40 and the second region 42 may be adjacent to each other, or they may be non-adjacent and separated by other regions or structures on the substrate 50. The first region 40 and the second region 42 may be used to form different cell types, such as system-on-chip (SOC) cells and high-performance computing (HPC) cells, respectively, on the same substrate 50.

In FIGS. 3A-3B, a first patterning process is performed to form the fin structures 61 in the first region 40 of the substrate 50. The first patterning process may also be performed as part of the processing steps that are used to form the fin structures 65 in the second region 42 of the substrate 50 as described subsequently in FIGS. 4A-4B. FIG. 3A illustrates a cross-sectional view of the first region 40 and the fin structures 61 along a reference line D-D’ that is shown in FIG. 3B. FIG. 3B illustrates a top-down view of the first region 40 after the first patterning process is performed to form the fin structures 61. The fin structures 61 may comprise fins 62A that are formed in the substrate 50 and nanostructures 64, 66 (including first dummy nanostructures 64A, second dummy nanostructures 64B, lower semiconductor nanostructures 66L, middle semiconductor nanostructures 66M, and upper semiconductor nanostructures 66U) that are formed in the multi-layer stack 52. In an embodiment, after the first patterning process, trenches 63 may be disposed between adjacent fin structures 61. In an embodiment, each trench 63 may have a width W1, and each fin structure 61 may have a width W2.

The fin structures 61 disposed in the first region 40 may be subsequently processed in order to form SOC cells 41 (shown in FIGS. 10C-10D). Each subsequently formed SOC cell 41 may be defined by a cell height H1 that is shown in the FIG. 3B, wherein the cell height H1 is equal to a sum of the width W2 of the fin structure 61 of the SOC cell 41 and the width W1 of a trench 63. As such, each fin structure 61 forms a first active region (that includes nanostructures 66 that subsequently act as channel regions) that is subsequently processed to form a corresponding SOC cell 41.

In some embodiments, the first patterning process may comprise forming the nanostructures 64, 66 and the fins 62A in the multi-layer stack 52 and the substrate 50 in the first region 40, respectively, by etching the trenches 63 in the multi-layer stack 52 and the substrate 50 in the first region 40. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 in the first region 40 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

The first patterning process that is used to form the fin structures 61 may comprise any suitable method. For example, the fins 62A and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 61 (e.g., including the fins 62A and the nanostructures 64, 66). In some embodiments, a mask (or other layer) may remain on the nanostructures 64, 66.

Although each of the fins 62A and the nanostructures 64, 66 are illustrated as having a constant width W2 throughout, in other embodiments, the fins 62A and/or the nanostructures 64, 66 may have tapered sidewalls such that the width W2 of each of the fins 62A and/or the nanostructures 64, 66 continuously increases in a direction towards the substrate 50. In such embodiments, each of the nanostructures 64, 66 may have a different width and be trapezoidal in shape.

As subsequently described in greater detail, various one of the nanostructures 64, 66 in the first region 40 will be removed to form channel regions of CFETs of the SOC cells 41. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

FIGS. 4A-4B illustrate the performing of the first patterning process (also described previously in FIGS. 3A-3B in relation to the formation of the fin structures 61 in the first region 40) and a subsequent second patterning process to form the fin structures 65 in the second region 42 of the substrate 50. FIG. 4A illustrates a cross-sectional view of the second region 42 and the fin structures 65 along a reference line E-E’ that is shown in FIG. 4B. FIG. 4B illustrates a top-down view of the second region 42 after the first patterning process (described previously in FIGS. 3A-3B) and the second patterning process are performed to form the fin structures 65. The fin structures 65 may comprise fins 62B that are formed in the substrate 50 and nanostructures 64, 66 (including first dummy nanostructures 64A, second dummy nanostructures 64B, lower semiconductor nanostructures 66L, middle semiconductor nanostructures 66M, and upper semiconductor nanostructures 66U) that are formed in the multi-layer stack 52.

During the performing of the first patterning process (described previously in FIGS. 3A-3B to form the fin structures 61 in the first region 40), a trench 67 is also formed in the multi-layer stack 52 and the substrate 50 in the second region 42, such that the trench 67 is disposed between first portions of the multi-layer stack 52 and the substrate 50, and second portions of the multi-layer stack 52 and the substrate 50. The first portions of the multi-layer stack 52 and the substrate 50 may be disposed in a first portion of the second region 42A, and the second portions of the multi-layer stack 52 and the substrate 50 may be disposed in a second portion of the second region 42B. In an embodiment, the trench 67 may have a width W3 that is larger than 30 nm.

After the first patterning process is performed, a second patterning process is performed to form the fin structures 65 in the second region 42. For example, a first trench 69 is formed in the first portions of the multi-layer stack 52 and the substrate 50 in the first portion of the second region 42A to form two fin structures 65 on opposite sides of the first trench 69, and a second trench 69 is formed in the second portions of the multi-layer stack 52 and the substrate 50 in the second portion of the second region 42B to form two fin structures 65 on opposite sides of the second trench 69. In an embodiment, each trench 69 may have a width W4 that is in a range from 5 nm to 30 nm. In an embodiment, each fin structure 65 may have a width W5. In an embodiment, the width W5 is greater than the width W2. In an embodiment, the width W3 is greater than the width W4. In an embodiment, a ratio of the width W3 of the trench 67 to the width W4 of the trench 69 is greater than 1:1, such as 2:1, 3:1, 4:1, 5:1, 6:1, 7:1, 8:1, or other suitable ratios greater than 1:1.

In various embodiments, the width difference between the trench 67 having the width W3 and the trench 69 having the width W4 may provide advantages. For example, the trench 67 having the larger width W3 may be able to provide space to accommodate future power rail routing that is disposed between subsequently formed HPC cells 43 (shown in FIGS. 10F-10G) in the second region 42. In contrast, the each trench 69, having the smaller width W4, does not need to provide space to accommodate such power rail routing within each subsequently formed HPC cell 43. This configuration may allow for a more efficient use of space while ensuring adequate power distribution across subsequently formed HPC cells in the second region 42.

The fin structures 65 disposed in the second region 42 may be subsequently processed to form HPC cells 43 (shown in FIGS. 10F-10G). Each subsequently formed HPC cell 43 may be defined by a cell height H2 that is shown in the FIG. 4B, wherein the cell height H2 is equal to a sum of the widths W5 of two fin structures 65 of the HPC cell 43, the width W4 of the trench 69 between the two fin structures, and the width W3 of a trench 67. As such, two adjacent fin structures 65 (also referred to as a pair of fin structures 65) that are separated by a trench 69 form corresponding second active regions (that includes nanostructures 66 that subsequently act as channel regions) that are subsequently processed to form a corresponding HPC cell 43. In this way, each HPC cell 43 will comprise two second active regions.

In some embodiments, the second patterning process may comprise forming nanostructures 64, 66 and the fins 62B in the multi-layer stack 52 and the substrate 50 in the second region 42, respectively, by etching the trenches 69 in the multi-layer stack 52 and the substrate 50 in the first portion of the second region 42A and the second portion of the second region 42B. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 in the first portion of the second region 42A and the second portion of the second region 42B may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. As was described previously in FIGS. 3A-3B, the first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

The second patterning process that is used to form the fin structures 65 may comprise any suitable method. For example, the fins 62B and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 65 (e.g., including the fins 62B and the nanostructures 64, 66). In some embodiments, a mask (or other layer) may remain on the nanostructures 64, 66.

In some embodiments, the first patterning process may be similar to the second patterning process, and may for example, use the same etchants, similar photolithography techniques, and/or or comparable multi-patterning approaches. In other embodiments, the first patterning process may be different to the second patterning process, and may for example, use different etchants, photolithography techniques and/or multi-patterning approaches.

Although each of the fins 62B and the nanostructures 64, 66 in the second region 42 are illustrated as having a constant width W5 throughout, in other embodiments, the fins 62B and/or the nanostructures 64, 66 may have tapered sidewalls such that the width W5 of each of the fins 62B and/or the nanostructures 64, 66 continuously increases in a direction towards the substrate 50. In such embodiments, each of the nanostructures 64, 66 may have a different width and be trapezoidal in shape.

As subsequently described in greater detail, various one of the nanostructures 64, 66 in the second region 42 will be removed to form channel regions of CFETs of the HPC cells 43. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

Advantages can be achieved by performing the first patterning process to form the fin structures 61 in the first region 40, each fin structure 61 having the width W2, the fin structures 61 comprising the nanostructures 64, 66 and the fins 62A in the multi-layer stack 52 and the substrate 50 in the first region 40, respectively. The first patterning process and the second patterning process are performed to form the fin structures 65 in the second region 42, each fin structure 65 having the width W5 that is greater than the width W2, the fin structures 65 comprising the nanostructures 64, 66 and the fins 62B in the multi-layer stack 52 and the substrate 50 in the second region 42, respectively. A first pair of adjacent fin structures 65 in the second region 42 may subsequently be used to form a first HPC cell 43, and a second pair of adjacent fin structures 65 in the second region 42 may be used subsequently to form a second HPC cell 43. The trench 67 (e.g., formed during the first patterning process) having the width W3 that is greater than 30 nm is disposed between the first pair of adjacent fin structures 65 and the second pair of adjacent fin structures 65, and the trench 69 (e.g., formed during the second patterning process) having the width W4 that is smaller than the width W3 and that is in a range from 5 nm to 30 nm (such that a ratio of the width W3 of the trench 67 to the width W4 of the trench 69 is greater than 1:1) is disposed between the fin structures 65 of each of the first pair of adjacent fin structures 65 and the second pair of adjacent fin structures 65.

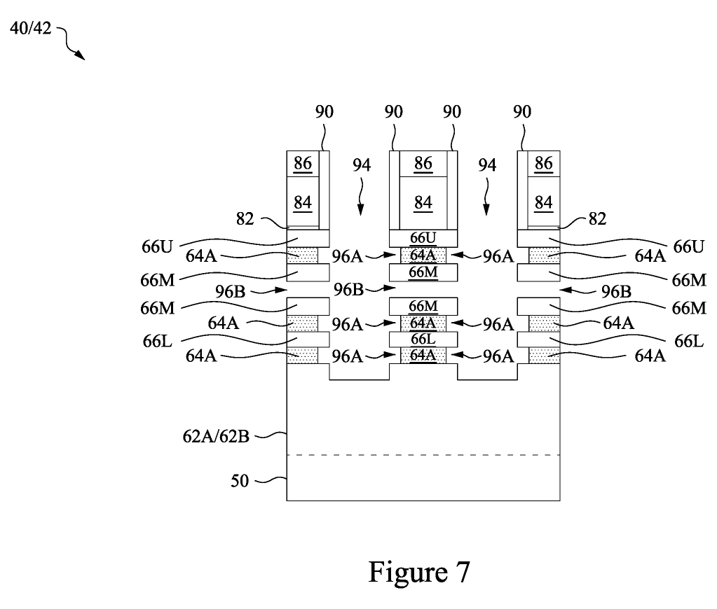

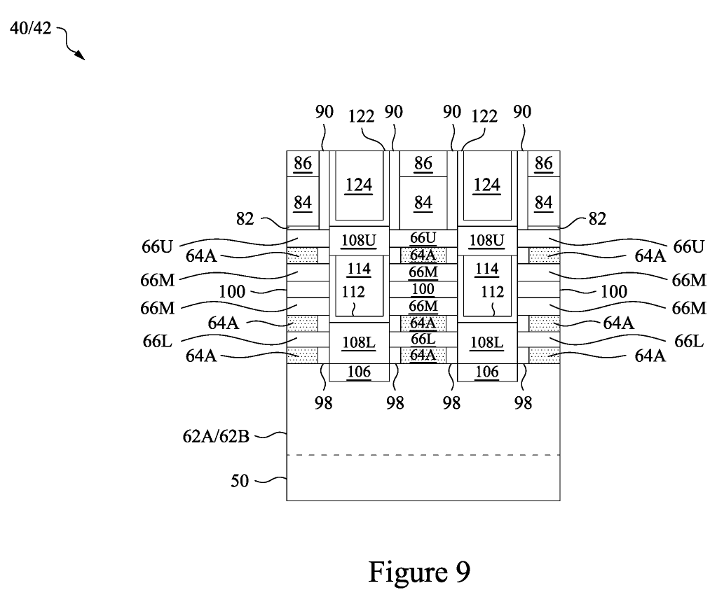

These advantages include allowing for the formation and integration of both SOC cells 41 (shown in FIGS. 10C-10D) and HPC cells 43 (shown in FIGS. 10F-10G) on a single wafer (e.g., using a hybrid cell configuration). As a result, device performance can be optimized for different application needs. In addition, the performing of both the first patterning process (to form the trench 67) and the subsequent second patterning process (to form the trenches 69) to form the fin structures 65, wherein each fin structure 65 has the width W5 that is greater than the width W2 of the fin structures 61 enables a larger effective channel width of the channel regions (e.g., formed from the lower semiconductor nanostructures 66L and the upper semiconductor nanostructures 66U in the corresponding pair of adjacent fin structures 65) of the first HPC cell 43 or the second HPC cell 43. This may result in enhanced device performance that is suitable for high-performance computing tasks. Further, the performing of the first patterning process and the second patterning process to form the trench 67 and the trenches 69, respectively, allows for an improved removal (e.g., having less material residues) of the nanostructures 64 (including the first dummy nanostructures 64A and the second dummy nanostructures 64B) from the fin structures 65 during subsequent etching processes (described in FIGS. 7 and 10A-10G). In addition, a reduction in the amount of sub-threshold swing degradation of subsequently formed CFETs of the first HPC cell 43 and the second HPC cell 43 may be achieved, while still maintaining the benefits of the larger effective channel widths of the channel regions of the first HPC cell 43 and the second HPC cell 43. Further, each fin structure 65 may be formed having only one lower semiconductor nanostructure 66L that will act as a channel region for a lower nanostructure-FET of a CFET, and one upper semiconductor nanostructure 66U that will act as a channel region for an upper nanostructure-FET of the CFET. As a result, multi-sheet channel epitaxy processes are not needed during subsequent epitaxial processes (described in FIG. 9) to form lower epitaxial source/drain regions 108L for the lower nanostructure-FET of the CFET and upper epitaxial source/drain regions 108U region for the upper nanostructure-FET of the CFET. This may further result in a simplification of the manufacturing process and improvements in device yield.

FIGS. 5A-5C illustrate the formation of isolation regions 70 over the substrate 50 and between adjacent fin structures 61 in the first region 40 (e.g., as shown in FIGS. 5A and 5B) and between adjacent fin structures 65 in the second region 42 (e.g., as shown in FIGS. 5A and 5C). The isolation regions 70 may include a liner and a fill material over the liner. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64, 66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) maybe recessed such that upper portions of the semiconductor fins 62A/62B and the nanostructures 64, 66 extend higher than the isolation regions 70.

The previously described process of FIGS. 3A-5C is just one example of how the fin structures 61 and 65 (including the fins 62A/62B and the nanostructures 64, 66) may be formed. In some embodiments, the fins 62A/62B and/or the nanostructures 64, 66 may be formed using a mask and an epitaxial growth process. For example, a dielectric layer can be formed over top surfaces of the substrate 50 in the first region 40 and the second region 42, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62A/62B and/or the nanostructures 64, 66. The epitaxial structures may comprise the previously described alternating semiconductor materials, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together. In an embodiment, the epitaxial structures may also comprise any number of additional nanostructures, such as optional nanostructures 59 shown in FIGS. 5B and 5C. The optional nanostructures 59 (not shown in subsequent Figures) may comprise any suitable semiconductor material, such as silicon germanium, or the like.

Further, appropriate wells (not separately illustrated) may be formed in the semiconductor nanostructures 66. For example, an n-type impurity implant and/or a p-type impurity implant may be performed, or the semiconductor materials may be in situ doped during growth. The n-type impurities may be phosphorus, arsenic, antimony, or the like at a concentration in a range from 10¹⁷ atoms/cm³ to 10¹⁹ atoms/cm³. The p-type impurities may be boron, boron fluoride, indium, or the like at a concentration in a range from 10¹⁷ atoms/cm³ to 10¹⁹ atoms/cm³. The wells in the lower semiconductor nanostructures 66L have a conductivity type opposite from a conductivity type of lower source/drain regions that will be subsequently formed adjacent the lower semiconductor nanostructures 66L. The wells in the upper semiconductor nanostructures 66U have a conductivity type opposite from a conductivity type of upper source/drain regions that will be subsequently formed adjacent the upper semiconductor nanostructures 66U.

Referring further to FIGS. 5A-5C, a dummy dielectric layer is formed over the fin structures 61 in the first region 40 and the fin structures 65 in the second region 42, such as on the fins 62A/62B and/or the nanostructures 64, 66. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be formed of other materials that have a high etching selectivity to insulating materials. The mask layer may include, for example, silicon nitride, silicon oxynitride, or the like. In the illustrated embodiment, the dummy dielectric layer covers the isolation regions 70, such that the dummy dielectric layer extends between the dummy gate layer and the isolation regions. In another embodiment, the dummy dielectric layer covers only the fins 62A/62B and/or the nanostructures 64, 66.

After the formation of the dummy gate layer, the dummy dielectric layer, and the mask layer, the mask layer may be patterned using acceptable photolithography and etching techniques to form masks 86. The pattern of the masks 86 then may be transferred to the dummy gate layer and to the dummy dielectric layer to form dummy gates 84 and dummy dielectrics 82, respectively. The dummy gates 84 cover respective channel regions of the nanostructures 64, 66 in the first region 40 and the second region 42. The pattern of the masks 86 may be used to physically separate each of the dummy gates 84 from adjacent dummy gates 84. The dummy gates 84 may also have a lengthwise direction substantially perpendicular to the lengthwise direction of respective fins 62A/62B. The masks 86 can optionally be removed after patterning, such as by any acceptable etching technique.

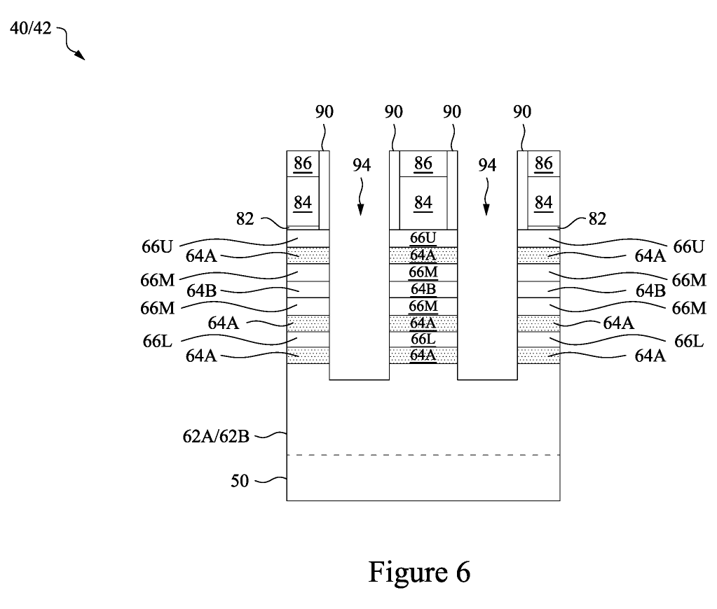

In FIG. 6, gate spacers 90 are formed in the first region 40 and the second region 42 over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). In some embodiments, the dielectric material(s), when etched, may also have portions left on the sidewalls of the fins 62A/62B and/or the nanostructures 64, 66.

Further, implants for lightly doped source/drain (LDD) regions (not separately illustrated) may be performed. The LDD implants may be performed before the gate spacers 90 are formed. Appropriate type impurities may be implanted into the nanostructures 64, 66 to a desired depth. The LDD regions may have a same conductivity type as a conductivity type of source/drain regions that will be subsequently formed adjacent the semiconductor nanostructures 66. Additionally, the LDD regions in the lower semiconductor nanostructures 66L may have a conductivity type opposite from a conductivity type of the LDD regions in the upper semiconductor nanostructures 66U. In some embodiments, the lower semiconductor nanostructures 66L have p-type LDD regions and the upper semiconductor nanostructures 66U have n-type LDD regions. In some embodiments, the lower semiconductor nanostructures 66L have n-type LDD regions and the upper semiconductor nanostructures 66U have p-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 10²⁰ atoms/cm³. An anneal may be used to repair implant damage and to activate the implanted impurities. In some embodiments, the grown materials of the nanostructures 64, 66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

Source/drain recesses 94 are formed in the fins 62A/62B, the nanostructures 64, 66, and the substrate 50 in the first region 40 and the second region 42. Epitaxial source/drain regions will be subsequently formed in the source/drain recesses 94. The source/drain recesses 94 may extend through the nanostructures 64, 66 and into the substrate 50. The fins 62A/62B may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the fins 62A/62B, the nanostructures 64, 66, and the substrate 50 using anisotropic etching processes, such as RIE, NBE, or the like. The gate spacers 90 and the dummy gates 84 mask portions of the fins 62A/62B, the nanostructures 64, 66, and the substrate 50 during the etching processes used to form the source/drain recesses 94. A single etch process or multiple etch processes may be used to etch each layer of the nanostructures 64, 66 and/or the fins 62A/62B. Timed etch processes may be used to stop the etching of the source/drain recesses 94 after the source/drain recesses 94 reach a desired depth.

In FIG. 7, the sidewalls of the first dummy nanostructures 64A exposed by the source/drain recesses 94 in the fin structures 61 (e.g. in the first region 40) and the fin structures 65 (e.g., in the second region 42) are recessed to form sidewall recesses 96A. Additionally, the second dummy nanostructures 64B are removed to form openings 96B between the lower semiconductor nanostructures 66L (collectively) and the upper semiconductor nanostructures 66U (collectively). The sidewall recesses 96A will subsequently be filled with spacers. The openings 96B will subsequently be filled with isolation structures.

The sidewall recesses 96A may be formed by recessing the sidewalls of the first dummy nanostructures 64A with any acceptable etch process. The etching is selective to the first dummy nanostructures 64A (e.g., selectively etches the material of the first dummy nanostructures 64A at a faster rate than the material of the semiconductor nanostructures 66). The etching may be isotropic. Although sidewalls of the first dummy nanostructures 64A are illustrated as being straight after the etching, the sidewalls may be concave or convex.

The openings 96B may be formed by removing the second dummy nanostructures 64B with any acceptable etch process. The etching is selective to the second dummy nanostructures 64B (e.g., selectively etches the material of the second dummy nanostructures 64B at a faster rate than the material of the semiconductor nanostructures 66). The etching may be isotropic. The dummy gates 84 may adhere to and support the upper semiconductor nanostructures 66U so that the upper semiconductor nanostructures 66U do not collapse after the formation of the openings 96B.

In some embodiments, the same etching process is used to recess the sidewalls of the first dummy nanostructures 64A and to remove the second dummy nanostructures 64B. For example, the second dummy nanostructures 64B may be completely removed without completely removing the first dummy nanostructures 64A, and the first dummy nanostructures 64A may be recessed without significantly recessing the semiconductor nanostructures 66. The etching process has selectivity among the materials of the first dummy nanostructures 64A, the second dummy nanostructures 64B, and the semiconductor nanostructures 66. Specifically, the etching process selectively etches the material of the first dummy nanostructures 64A at a faster rate than the material of the semiconductor nanostructures 66, and also selectively etches the material of the second dummy nanostructures 64B at a faster rate than the material of the first dummy nanostructures 64A. Thus, the etch rate of the first dummy nanostructures 64A is less than the etch rate of the second dummy nanostructures 64B and is greater than the etch rate of the semiconductor nanostructures 66. In some embodiments where the second dummy nanostructures 64B are formed of germanium or silicon germanium with a high germanium atomic percentage, the first dummy nanostructures 64A are formed of silicon germanium with a low germanium atomic percentage, and the semiconductor nanostructures 66 are formed of silicon free from germanium, the etch process may comprise a dry etch process using chlorine gas, with or without a plasma.

The middle semiconductor nanostructures 66M are exposed by the openings 96B. In some embodiments, the etching process thins the middle semiconductor nanostructures 66M. Accordingly, the thickness of the middle semiconductor nanostructures 66M may be different (e.g., less than) the thickness of the lower semiconductor nanostructures 66L and the thickness of the upper semiconductor nanostructures 66U. In some embodiments, the middle semiconductor nanostructures 66M are from 0% to 20% thinner than the lower semiconductor nanostructures 66L and the upper semiconductor nanostructures 66U after the etching process.

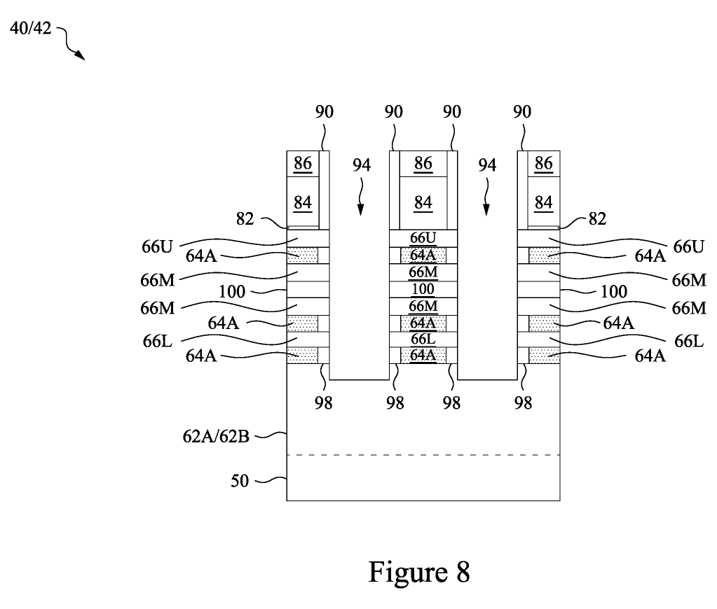

In FIG. 8, inner spacers 98 are formed in the sidewall recesses 96A and on the sidewalls of the remaining portions of the first dummy nanostructures 64A in the fin structures 61 (e.g., in the first region 40) and the fin structures 65 (e.g., in the second region 42). As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures. Additionally, isolation structures 100 are formed in the openings 96B and between the middle semiconductor nanostructures 66M. The isolation structures 100 and the middle semiconductor nanostructures 66M will define the boundaries of the lower nanostructure-FETs and the upper nanostructure-FETs.

The inner spacers 98 and the isolation structures 100 may be formed by conformally forming an insulating material in the source/drain recesses 94, the sidewall recesses 96A, and the openings 96B, and then subsequently etching the insulating material. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses 96A (thus forming the inner spacers 98) and has portions remaining in the openings 96B (thus forming the isolation structures 100).

Although outer sidewalls of the inner spacers 98 and the isolation structures 100 are illustrated as being flush with sidewalls of the semiconductor nanostructures 66, the outer sidewalls of the inner spacers 98 and the isolation structures 100 may extend beyond or be recessed from sidewalls of the semiconductor nanostructures 66. Thus, the inner spacers 98 and the isolation structures 100 may partially fill, completely fill, or overfill the sidewall recesses 96A and the openings 96B, respectively. Moreover, although the sidewalls of the inner spacers 98 and the isolation structures 100 are illustrated as being straight, those sidewalls may be concave or convex.

The isolation structures 100 have similar dimensions as the second dummy nanostructures 64B they replaced. Accordingly, the isolation structures 100 may have a large thickness, such as a greater thickness than the semiconductor nanostructures 66 and the first dummy nanostructures 64A, or the isolation structures 100 may have a small thickness, such as a lesser thickness than the semiconductor nanostructures 66 and the first dummy nanostructures 64A. In some embodiments, the isolation structures 100 are from 60% to 90% thinner than the semiconductor nanostructures 66 and the isolation structures 100 are from 40% to 90% thinner than the first dummy nanostructures 64A.

In FIG. 9, lower epitaxial source/drain regions 108L and upper epitaxial source/drain regions 108U are formed in the source/drain recesses 94 in the fin structures 61 (e.g., in the first region 40) and the fin structures 65 (e.g., in the second region 42). A first contact etch stop layer (CESL) 112 and/or a first inter-layer dielectric (ILD) 114 may also be formed in the source/drain recesses 94. The first ILD 114 is between the upper epitaxial source/drain regions 108U and the lower epitaxial source/drain regions 108L. The lower epitaxial source/drain regions 108L are for lower nanostructure-FETs of the CFETs, and the upper epitaxial source/drain regions 108U are for upper nanostructure-FETs of the CFETs. The first ILD 114 thus acts as isolation regions to prevent shorting of the lower and upper nanostructure-FETs. Additionally, a second CESL 122 and/or a second ILD 124 may be formed on the upper epitaxial source/drain regions 108U.

The lower epitaxial source/drain regions 108L are in contact with the lower semiconductor nanostructures 66L and are not in contact with the upper semiconductor nanostructures 66U. In some embodiments, the lower epitaxial source/drain regions 108L exert stress in the respective channel regions of the lower semiconductor nanostructures 66L, thereby improving performance. The lower epitaxial source/drain regions 108L are formed in the source/drain recesses 94 such that each lower semiconductor nanostructure 66L is disposed between respective neighboring pairs of the lower epitaxial source/drain regions 108L. In some embodiments, the inner spacers 98 are used to separate the lower epitaxial source/drain regions 108L from the first dummy nanostructures 64A, which will be replaced with gate structures in subsequent processes.

The lower epitaxial source/drain regions 108L are epitaxially grown in the lower portions of the source/drain recesses 94. For example, the lower epitaxial source/drain regions 108L may be grown laterally from exposed sidewalls of the lower semiconductor nanostructures 66L. During the epitaxy of the lower epitaxial source/drain regions 108L, the middle semiconductor nanostructures 66M and/or the upper semiconductor nanostructures 66U may be masked to prevent undesired epitaxial growth on the middle semiconductor nanostructures 66M and/or the upper semiconductor nanostructures 66U. After the lower epitaxial source/drain regions 108L are grown, the masks on the middle semiconductor nanostructures 66M and/or the upper semiconductor nanostructures 66U may then be removed. The lower epitaxial source/drain regions 108L have a conductivity type that is suitable for the device type of the lower nanostructure-FETs. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, carbon-doped silicon, phosphorous-doped silicon, silicon phosphide, silicon arsenide, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, boron-doped silicon, germanium, germanium tin, or the like. The lower epitaxial source/drain regions 108L may have surfaces raised from respective upper surfaces of the lower semiconductor nanostructures 66L and may have facets.

The lower epitaxial source/drain regions 108L may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the lower epitaxial source/drain regions 108L are in situ doped during growth.

As a result of the epitaxy processes used to form the lower epitaxial source/drain regions 108L, upper surfaces of the lower epitaxial source/drain regions 108L have facets which expand laterally outward beyond sidewalls of the nanostructures 64, 66. In some embodiments, adjacent lower epitaxial source/drain regions 108L remain separated after the epitaxy process is completed. In other embodiments, these facets cause adjacent lower epitaxial source/drain regions 108L of a same nanostructure-FET to merge.

The first ILD 114 is formed over the lower epitaxial source/drain regions 108L. The first ILD 114 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The first CESL 112 may be formed between the first ILD 114 and the lower epitaxial source/drain regions 108L. The first CESL 112 may be formed of a dielectric material having a high etching selectivity to the dielectric material of the first ILD 114, such as silicon nitride, silicon oxide, silicon oxynitride, or the like, which may be formed by any suitable deposition process, such as CVD, ALD, or the like.

The first CESL 112 and/or the first ILD 114 may be formed by depositing a material for the first CESL 112 and depositing a material for the first ILD 114, followed by an etch-back process. In some embodiments, the first ILD 114 is initially etched, leaving the first CESL 112 unetched. An anisotropic etching process is then performed to remove the portions of the first CESL 112 that are higher than the first ILD 114. After the recessing, the sidewalls of the upper semiconductor nanostructures 66U are exposed.

The upper epitaxial source/drain regions 108U are in contact with the upper semiconductor nanostructures 66U and are not in contact with the lower semiconductor nanostructures 66L. In some embodiments, the upper epitaxial source/drain regions 108U exert stress in the respective channel regions of the upper semiconductor nanostructures 66U, thereby improving performance. The upper epitaxial source/drain regions 108U are formed in the source/drain recesses 94 such that each upper semiconductor nanostructure 66U is disposed between respective neighboring pairs of the upper epitaxial source/drain regions 108U. In some embodiments, the inner spacers 98 are used to separate the upper epitaxial source/drain regions 108U from the first dummy nanostructures 64A, which will be replaced with gate structures in subsequent processes.

The upper epitaxial source/drain regions 108U are epitaxially grown in the upper portions of the source/drain recesses 94. For example, the upper epitaxial source/drain regions 108U may be grown laterally from exposed sidewalls of the upper semiconductor nanostructures 66U. The upper epitaxial source/drain regions 108U have a conductivity type that is suitable for the device type of the upper nanostructure-FETs. The conductivity type of the upper epitaxial source/drain regions 108U may be opposite the conductivity type of the lower epitaxial source/drain regions 108L. Put another way, the upper epitaxial source/drain regions 108U may be oppositely doped from the lower epitaxial source/drain regions 108L. In some embodiments, the upper epitaxial source/drain regions 108U are n-type source/drain regions. For example, if the upper semiconductor nanostructures 66U are silicon, the upper epitaxial source/drain regions 108U may include materials exerting a tensile strain on the upper semiconductor nanostructures 66U, such as silicon, carbon-doped silicon, phosphorous-doped silicon, silicon phosphide, silicon arsenide, or the like. In some embodiments, the upper epitaxial source/drain regions 108U are p-type source/drain regions. For example, if the upper semiconductor nanostructures 66U are silicon-germanium, the upper epitaxial source/drain regions 108U may include materials exerting a compressive strain on the upper semiconductor nanostructures 66U, such as silicon-germanium, boron-doped silicon-germanium, boron-doped silicon, germanium, germanium tin, or the like. The upper epitaxial source/drain regions 108U may have surfaces raised from respective upper surfaces of the upper semiconductor nanostructures 66U and may have facets.

The upper epitaxial source/drain regions 108U may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the upper epitaxial source/drain regions 108U are in situ doped during growth.

As a result of the epitaxy processes used to form the upper epitaxial source/drain regions 108U, upper surfaces of the upper epitaxial source/drain regions 108U have facets which expand laterally outward beyond sidewalls of the nanostructures 64, 66. In some embodiments, adjacent upper epitaxial source/drain regions 108U remain separated after the epitaxy process is completed. In other embodiments, these facets cause adjacent upper epitaxial source/drain regions 108U of a same nanostructure-FET to merge.

The second ILD 124 is deposited over the upper epitaxial source/drain regions 108U. The second ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

The second CESL 122 may be formed between the second ILD 124 and the upper epitaxial source/drain regions 108U. The second CESL 122 may be formed of a dielectric material having a high etching selectivity to the dielectric material of the second ILD 124, such as, silicon nitride, silicon oxide, silicon oxynitride, or the like, which may be formed by any suitable deposition process, such as CVD, ALD, or the like.

The second CESL 122 and/or the second ILD 124 may be formed by depositing a material for the second CESL 122 and depositing a material for the second ILD 124. A removal process is then performed to level the top surfaces of the second ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 124, the gate spacers 90, and the masks 86 (if present) or the dummy gates 84 are substantially coplanar (within process variations). Accordingly, the top surfaces of the masks 86 (if present) or the dummy gates 84 are exposed through the second ILD 124. In the illustrated embodiment, the masks 86 remain after the removal process. In other embodiments, the masks 86 are removed such that the top surfaces of the dummy gates 84 are exposed through the second ILD 124.

Optionally, semiconductor layers 106 are formed between the lower epitaxial source/drain regions 108L and the fins 62A/62B. The semiconductor layers 106 may be formed of a semiconductor material selected from the candidate semiconductor materials of the substrate 50, which may be grown by an epitaxial growth process such as vapor phase epitaxy (VPE), molecular beam epitaxy (MBE), or the like. The semiconductor layers 106 may be undoped semiconductor layers. In some embodiments, the semiconductor layers 106 are formed of undoped silicon or undoped silicon germanium. The semiconductor layers 106 may be provided to improve isolation between adjacent lower epitaxial source/drain regions 108L, reducing leakage from the lower epitaxial source/drain regions 108L through the underlying fins 62A/62B and/or substrate 50.

In FIGS. 10A-10G, the dummy gates 84 in the first region 40 and the second region 42 are removed in one or more etching steps, so that recesses are formed between the gate spacers 90. Portions of the dummy dielectrics 82 in the recesses are also removed. Gate dielectrics 132 and gate electrodes 134 (including lower gate electrodes 134L and upper gate electrodes 134U) are then formed in the recesses in the first region 40 and the second region 42 to form replacement gates. FIG. 10A illustrates a cross-sectional view in the first region 40 or the second region 42 along reference line A-A’ of FIG. 1. FIG. 10B illustrates a top-down view of the fin structures 61 in the first region 40 after the formation of the gate dielectrics 132 and the gate electrodes 134 as replacement gates. FIG. 10C illustrates a cross-sectional view along reference line F-F’ of FIG. 10B. FIG. 10D illustrates a cross-sectional view along reference line G-G’ of FIG. 10B. FIG. 10E illustrates a top-down view of the fin structures 65 in the second region 42 after the formation of the gate dielectrics 132 and the gate electrodes 134 as replacement gates. FIG. 10F illustrates a cross-sectional view along reference line H-H’ of FIG. 10E. FIG. 10G illustrates a cross-sectional view along reference line I-I’ of FIG. 10E. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 124, the isolation structures 100, the inner spacers 98, and the gate spacers 90. Each recess between the gate spacers 90 exposes and/or overlies portions of nanostructures 64, 66 which act as the channel regions in the resulting devices. The portions of the nanostructures 64, 66 which act as the channel regions in the first region 40 and the second region 42 are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A of the fin structures 61 (e.g., in the first region 40) and the fin structures 65 (e.g., in the second region 42) are then removed to form openings in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings between the semiconductor nanostructures 66.

Next, gate dielectrics 132 and gate electrodes 134 (including lower gate electrodes 134L and upper gate electrodes 134U) are formed for replacement gates. Each respective pair of a gate dielectric 132 and a gate electrode 134 (including an upper gate electrode 134U and/or a lower gate electrode 134L) may be collectively referred to as a “gate structure.” Each gate structure extends along at least three sides (e.g., a top surface, a sidewall, and a bottom surface) of a channel region of a semiconductor nanostructure 66. The gate structures may also extend along sidewalls and/or a top surface of a semiconductor fin 62A/62B.

The gate dielectrics 132 include one or more gate dielectric layer(s) disposed around the lower semiconductor nanostructures 66L, the upper semiconductor nanostructures 66U, and the isolation structures 100. Specifically, the gate dielectrics 132 are disposed on the top surfaces of the fins 62A/62B; on the top surfaces, the sidewalls, and the bottom surfaces of the semiconductor nanostructures 66; and on the sidewalls of the gate spacers 90. The gate dielectrics 132 wrap around all (e.g., four) sides of the semiconductor nanostructures 66. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

The lower gate electrodes 134L include one or more gate electrode layer(s) disposed over the gate dielectrics 132 and around the lower semiconductor nanostructures 66L. The lower gate electrodes 134L are disposed in the lower portions of the recesses between the gate spacers 90 and in the openings between the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of work function tuning metal(s) that are suitable for the device type of the lower nanostructure-FETs. In some embodiments, the lower gate electrodes 134L include an n-type work function tuning layer, which may be formed of an n-type work function tuning metal such as titanium aluminum, titanium aluminum carbide, tantalum aluminum, tantalum carbide, combinations thereof, or the like. In some embodiments, the lower gate electrodes 134L include a p-type work function tuning layer, which may be formed of a p-type work function tuning metal such as titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The upper gate electrodes 134U include one or more gate electrode layer(s) disposed over the gate dielectrics 132 and around the upper semiconductor nanostructures 66U. The upper gate electrodes 134U are disposed in the upper portions of the recesses between the gate spacers 90 and in the openings between the upper semiconductor nanostructures 66U. The upper gate electrodes 134U may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the upper gate electrodes 134U may include any number of work function tuning layers, any number of barrier layers, any number of glue layers, and a fill material.

The upper gate electrodes 134U are formed of material(s) that are suitable for the device type of the upper nanostructure-FETs. For example, the upper gate electrodes 134U may include one or more work function tuning layer(s) formed of work function tuning metal(s) that are suitable for the device type of the upper nanostructure-FETs. In some embodiments, the upper gate electrodes 134U include an n-type work function tuning layer, which may be formed of an n-type work function tuning metal such as titanium aluminum, titanium aluminum carbide, tantalum aluminum, tantalum carbide, combinations thereof, or the like. In some embodiments, the upper gate electrodes 134U include a p-type work function tuning layer, which may be formed of a p-type work function tuning metal such as titanium nitride, tantalum nitride, combinations thereof, or the like. The work function tuning metal(s) of the upper gate electrodes 134U may be different than the work function tuning metal(s) of the lower gate electrodes 134L. Additionally or alternatively, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L.

In some embodiments, isolation layers (not separately illustrated) are formed between the lower gate electrodes 134L and the upper gate electrodes 134U. The isolation layers act as isolation features between the lower gate electrodes 134L and the upper gate electrodes 134U. The isolation layers may be formed of a dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. In embodiments where the isolation layers are formed, the isolation layers and the isolation structures 100 together isolate the upper gate electrodes 134U from the lower gate electrodes 134L. Accordingly, an upper nanostructure-FET may be isolated from a lower nanostructure-FET by a combination of an isolation structure 100 and an isolation layer. In some embodiments where the isolation layers are omitted, an upper nanostructure-FET may be coupled to a lower nanostructure-FET. When the isolation layers are omitted, the lower gate electrodes 134L may be physically and electrically coupled to the upper gate electrodes 134U.

As an example to form the gate structures, one or more gate dielectric layer(s) may be deposited in the recesses between the gate spacers 90 and the openings between the semiconductor nanostructures 66. The gate dielectric layer(s) may also be deposited on the top surfaces of the second ILD 124 and the gate spacers 90. Subsequently, one or more lower gate electrode layer(s) may be deposited on the gate dielectric layer(s), and in the remaining portions of the recesses between the gate spacers 90 and the openings between the semiconductor nanostructures 66. The lower gate electrode layer(s) may then be recessed. Any acceptable etch process, such as a dry etch, a wet etch, the like, or a combination thereof, may be performed to recess the lower gate electrode layer(s). The etching may be isotropic, such as an etch-back process that removes the lower gate electrode layer(s) from the upper portions of the recesses between the gate spacers 90, such that the lower gate electrode layer(s) remain in the openings between the lower semiconductor nanostructures 66L. In embodiments where the isolation layers are formed, an isolation material is conformally formed on the lower gate electrode layer(s) and then recessed. Any acceptable etch process, such as a dry etch, a wet etch, the like, or a combination thereof, may be performed to recess the isolation material. Subsequently, one or more upper gate electrode layer(s) may be deposited on the isolation material (if present) or the lower gate electrode layer(s), and in the remaining portions of the recesses between the gate spacers 90 and the openings between the upper semiconductor nanostructures 66U. A removal process is performed to remove the excess portions of the upper gate electrode layer(s), which excess portions are over the top surfaces of the gate spacers 90 and the second ILD 124, such that the upper gate electrode layer(s) remain in the openings between the upper semiconductor nanostructures 66U. In some embodiments, a planarization process such as a chemical mechanical polish (CMP), an etch-back process, combinations thereof, or the like may be utilized. The gate dielectric layer(s), after the removal process, have portions remaining in the recesses between the gate spacers 90 and the openings between the semiconductor nanostructures 66 (thus forming the gate dielectrics 132). The lower gate electrode layer(s), after the removal process, have portions left in the lower portions of the recesses between the gate spacers 90 and in the openings between the lower semiconductor nanostructures 66L (thus forming the lower gate electrodes 134L). The upper gate electrode layer(s), after the removal process, have portions left in the upper portions of the recesses between the gate spacers 90 and in the openings between the upper semiconductor nanostructures 66U (thus forming the upper gate electrodes 134U). When a planarization process is utilized, the top surfaces of the gate spacers 90, the second ILD 124, the gate dielectrics 132, and the upper gate electrodes 134U are coplanar (within process variations).

After the formation of the gate structures (e.g., including the gate dielectrics 132 and the gate electrodes 134, isolation structures 160 may be formed in the first region 40 to form individual gate stacks 162 (e.g., as shown in the FIGS. 10C-10D) from the gate structures 132/134 for corresponding SOC cells 41, wherein each gate stack 162 of a SOC cell 41 is electrically isolated from the other gate stacks 162 of the other SOC cells 41. The isolation structures 160 may also be formed in the second region 42 to form individual gate stacks 164 (e.g., as shown in FIGS. 10F-10G) from the gate structures 132/134 for corresponding HPC cells 43, wherein each gate stack 164 of a HPC cell 43 is electrically isolated from the other gate stacks 164 of the other HPC cells 43. The isolation structures 160 are formed by first forming a mask layer (e.g., a photoresist, or the like) over the gate structures 132/134 in the first region 40 and the second region 42 and patterning the mask layer using acceptable photolithography techniques to define the regions where the isolation structures 160 will be formed. An etching process, such as anisotropic dry etching, may then be performed to remove portions of the upper gate electrode 134U, lower gate electrode 134L, the gate dielectrics 132, and the isolation regions 70 in the exposed areas, creating trenches that separate the gate structures 132/134. Following the etching, a dielectric material is deposited to fill these trenches. The dielectric material may comprise a material such as silicon oxide, silicon nitride, or low-k dielectrics, or the like, that may be deposited using chemical vapor deposition (CVD), atomic layer deposition (ALD), or the like. The dielectric material may then be planarized, for example using chemical mechanical polishing (CMP), or the like, such that the remaining dielectric material in the trenches forms the isolation structures 160. After the planarization process, top surface of the gate stacks 162/164 may be level with top surfaces of the isolation structures 160. The formation of the isolation structures 160 provides some advantages. For example, the isolation structures 160 effectively separate and electrically isolate adjacent gate stacks 162 in the SOC cells 41 and adjacent gate stacks 164 in the HPC cells 43. The isolation structures 160 may allow for independent control of transistors within each SOC cell 41 or HPC cell 43, preventing electrical interference between neighboring gate stacks 162/164. As a result, different voltages may be applied to the different gate stacks 162/164 of corresponding SOC cells 41 and HPC cells 43, and as such, this allows for the different SOC cells 41 and HPC cells 43 to operate under different threshold voltages or be optimized for different operational voltages.

As can be seen in FIGS. 10B-10D, and as described previously, each SOC cell 41 may be formed from a corresponding fin structure 61 (e.g., comprising a first active region) in the first region 40, wherein the SOC cell 41 has the cell height H1. As can be seen in FIGS. 10E-10G, and as described previously, each HPC cell 43 may be formed from two adjacent fin structures 65 (e.g., each fin structure 65 comprising a corresponding second active region) in the second region 42, the HPC cell 43 having the cell height H2 which is greater than the cell height H1. As a result, the HPC cell 43 may have a greater overall width and a larger effective channel width as compared to the SOC cell 41. Although FIGS. 10B and 10E show that three gate structures (e.g., including the gate dielectrics 132 and the gate electrodes 134) are formed over each of the fin structures 61 and the fin structures 65, any number of gate structures can be formed over each of the fin structures 61 and the fin structures 65.

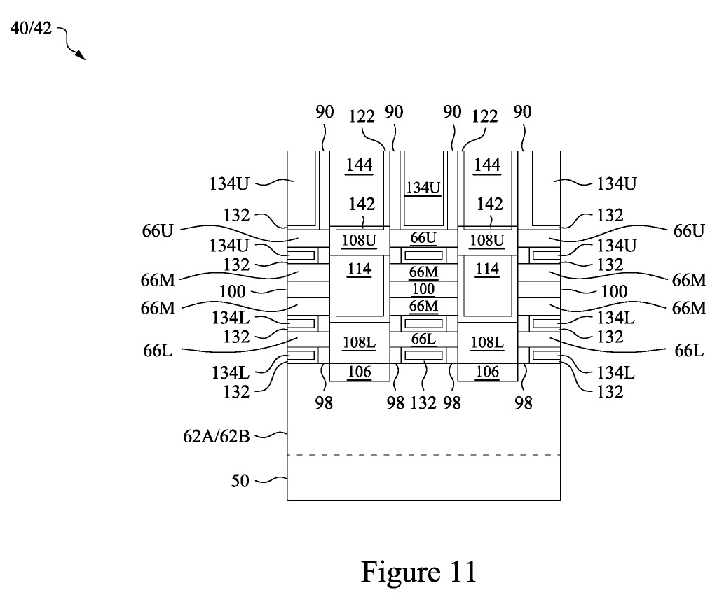

In FIG. 11, source/drain contacts 144 are formed through the second ILD 124 in the first region 40 and the second region 42 to electrically couple to the upper epitaxial source/drain regions 108U and/or the lower epitaxial source/drain regions 108L. As an example to form the source/drain contacts 144, openings for the source/drain contacts 144 are formed through the second ILD 124 and the second CESL 122. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90, the second CESL 122, and the upper gate electrodes 134U. The remaining liner and conductive material form the source/drain contacts 144 in the openings. In some embodiments, a planarization process such as a chemical mechanical polish (CMP), an etch-back process, combinations thereof, or the like is utilized. After the planarization process, the top surfaces of the gate spacers 90, the second ILD 124 (see FIG. 10A), the upper gate electrodes 134U, and the source/drain contacts 144 are substantially coplanar (within process variations).

Optionally, metal-semiconductor alloy regions 142 are formed at the interfaces between the source/drain regions 108 and the source/drain contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the source/drain regions 108 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 142. The material(s) of the source/drain contacts 144 can then be formed on the metal-semiconductor alloy regions 142.

In FIGS. 12A-12C, a third ILD 154 is deposited over the gate spacers 90, the second ILD 124, the upper gate electrodes 134U, and the source/drain contacts 144 in the first region 40 (e.g., shown in FIGS. 12A-12B) and the second region 42 (e.g., shown in FIGS. 12A and 12C). In some embodiments, the third ILD 154 is a flowable film formed by a flowable CVD method, which is subsequently cured. In some embodiments, the third ILD 154 is formed of a dielectric material such as PSG, BSG, BPSG, USG, or the like, which may be deposited by any suitable method, such as CVD, PECVD, or the like.

In some embodiments, an etch stop layer (ESL) 152 is formed between the third ILD 154 and the gate spacers 90, the second ILD 124, the upper gate electrodes 134U, and the source/drain contacts 144. The ESL 152 may include a dielectric material having a high etching selectivity to the dielectric material of the third ILD 154, such as, silicon nitride, silicon oxide, silicon oxynitride, or the like.

Gate contacts 156 and source/drain vias 158 are formed through the third ILD 154 to electrically couple to, respectively, the upper gate electrodes 134U and the source/drain contacts 144. For example, each gate contact 156 maybe electrically coupled to a corresponding gate stack 162 of a SOC cell 41 (e.g., as shown in FIG. 12B) or a corresponding gate stack 164 of a HPC cell 43 (e.g., as shown in FIG. 12C). This configuration allows for the independent control of each SOC cell 41 or HPC cell 43 gate. As an example to form the gate contacts 156 and the source/drain vias 158, openings for the gate contacts 156 and the source/drain vias 158 are formed through the third ILD 154 and the ESL 152. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 154. The remaining liner and conductive material form the gate contacts 156 and the source/drain vias 158 in the openings. The gate contacts 156 and the source/drain vias 158 may be formed in distinct processes, or may be formed in the same process. Although shown as being formed in the same cross-section, it should be appreciated that each of the gate contacts 156 and the source/drain vias 158 may be formed in different cross-sections, which may avoid shorting of the contacts.

The active devices as illustrated are collectively referred to as a device layer. In some embodiments, contacts to the lower gate electrodes 134L and the lower epitaxial source/drain regions 108L may be made through a backside of the device layer (e.g., a side opposite to the source/drain contacts 144).

The embodiments of the present disclosure have some advantageous features. The embodiments include forming a semiconductor device that includes a plurality of system-on-chip (SOC) cells and a plurality of high-performance computing (HPC) cells that are formed in a single wafer. For example, the plurality of SOC cells may be formed in a first region of the wafer and the plurality of HPC cells may be formed in a second region of the wafer. Each SOC cell and HPC cell may comprise complementary field-effect transistors (CFETs). The semiconductor device may be formed by first forming channel layers and dummy layers alternatingly over a substrate to form a multi-layer stack. The multi-layer stack may be then patterned to form first fin structures in a first region for corresponding SOC cells, and second fin structures in a second region for corresponding HPC cells. Each first fin structure may comprise first dummy nanostructures and first channel nanostructures formed from the dummy layers and the channel layers, respectively. The first channel nanostructures of each first fin structure may form part of a first active region of a subsequently formed SOC cell. The channel layers of each second fin structure may form part of a subsequently formed HPC cell, wherein first trenches are disposed between adjacent second fin structures. A width of each first fin structure is smaller than a width of each second fin structure. After the first fin structures and the second fin structures are formed, each second fin structure is patterned further to form a pair of third fin structures that are disposed on opposite sides of a second trench. The width of each first fin structure is smaller than a width of each third fin structure, and a width of each first trench is greater than a width of each second trench. Each third fin structure of the pair of third fin structures may comprise second dummy nanostructures and second channel nanostructures formed from the dummy layers and the channel layers, respectively, wherein the second channel nanostructures of each third fin structure of the pair of third fin structures may form part of a second active region of a subsequently formed HPC cell. The HPC cell may therefore comprise two second active regions.

One or more embodiments disclosed herein may allow for the integration of both system-on-chip (SOC) cells and high-performance computing (HPC) cells on a single wafer (e.g., using a hybrid cell configuration). As a result, device performance can be optimized for different application needs. In addition, the further patterning of each second fin structure to form the pair of third fin structures that are disposed on opposite sides of the second trench, wherein the width of each first fin structure is smaller than the width of each third fin structure enables larger effective widths of the second active regions of the subsequently formed HPC cell. This may result in enhanced device performance that is suitable for high-performance computing tasks. Further, the formation of the second trench may allow for an improved removal (e.g., having less material residues) of the second dummy nanostructures from the third fin structures during a subsequent etching process, as well as a reduction in the amount of sub-threshold swing degradation of the subsequently formed CFETs, while still maintaining the benefits of the larger effective widths of the second active regions. In addition, a need for challenging multi-sheet channel epitaxy processes is eliminated by avoiding multi-sheet channel formation. As a result, the manufacturing process is simplified and yield improvements can be achieved.

In accordance with an embodiment, a semiconductor device includes a first cell including a first active region and a second active region adjacent to the first active region, where each of the first active region and the second active region includes a first nanostructure extending between first source/drain regions; and a second nanostructure over the first nanostructure, the second nanostructure extending between second source/drain regions; and a first gate stack around the first nanostructure of the first active region and the first nanostructure of the second active region; and a second gate stack over the first gate stack and disposed around the second nanostructure of the first active region and the second nanostructure of the second active region. In an embodiment, a width between a first sidewall of the first active region and a first sidewall of the second active region that faces the first sidewall of the first active region is in a range from 5 nm to 30 nm. In an embodiment, the semiconductor device further includes a second cell adjacent to the first cell, the second cell including a third active region and a fourth active region adjacent to the third active region, where each of the third active region and the fourth active region includes a third nanostructure extending between third source/drain regions; and a fourth nanostructure over the third nanostructure, the fourth nanostructure extending between fourth source/drain regions; and the first gate stack around the third nanostructure of the third active region and the third nanostructure of the fourth active region; and the second gate stack over the first gate stack and disposed around the fourth nanostructure of the third active region and the fourth nanostructure of the fourth active region. In an embodiment, a width between a second sidewall of the second active region and a first sidewall of the third active region that faces the second sidewall of the second active region is greater than 30 nm. In an embodiment, the semiconductor device further includes an isolation structure extending through the first gate stack and the second gate stack to electrically isolate a first portion of the first gate stack from a second portion of the first gate stack, and a first portion of the second gate stack from a second portion of the second gate stack. In an embodiment, the isolation structure is disposed between the second sidewall of the second active region and the first sidewall of the third active region. In an embodiment, the first gate stack includes a first gate electrode, the second gate stack includes a second gate electrode, and where a material of the first gate electrode is different from a material of the second gate electrode. In an embodiment, the semiconductor device further includes a first gate contact over and electrically coupled to the first portion of the second gate stack, and a second gate contact over and electrically coupled to the second portion of the second gate stack.

In accordance with an embodiment, a method includes forming a multi-layer stack over a semiconductor substrate, the multi-layer stack including alternating semiconductor channel layers and dummy layers; forming a first trench in the multi-layer stack and the semiconductor substrate to form first fin structures on opposite sides of the first trench; forming a second trench in each first fin structure to form second fin structures on opposite sides of the second trench, where each second fin structure includes semiconductor nanostructures defined from the semiconductor channel layers, and dummy nanostructures defined from the dummy layers, where a first width of the first trench is greater than 30 nm, and the first width is greater than a second width of the second trench; epitaxially growing lower source/drain regions in each second fin structure, where a lower semiconductor nanostructure of the semiconductor nanostructures extends between the lower source/drain regions in each second fin structure; and epitaxially growing upper source/drain regions over the lower source/drain regions in each second fin structure, where an upper semiconductor nanostructure of the semiconductor nanostructures extends between the upper source/drain regions in each second fin structure. In an embodiment, the method further includes replacing the dummy nanostructures of each second fin structure with a lower gate stack around the lower semiconductor nanostructure of the second fin structure and an upper gate stack around the upper semiconductor nanostructure of the second fin structure. In an embodiment, the lower gate stack is electrically coupled to the upper gate stack. In an embodiment, the method further includes forming an isolation structure that extends through the lower gate stack and the upper gate stack, where the isolation structure electrically isolates a first portion of the lower gate stack from a second portion of the lower gate stack, and a first portion of the upper gate stack from a second portion of the upper gate stack. In an embodiment, the second width is in a range from 5 nm to 30 nm. In an embodiment, a ratio of the first width to the second width is 2:1, 3:1, 4:1, 5:1, 6:1, 7:1, or 8:1.

In accordance with an embodiment, a semiconductor device includes a first cell including a first active region and a second active region adjacent to the first active region, where each of the first active region and the second active region includes a first nanostructure extending between first source/drain regions; and a second nanostructure over the first nanostructure, the second nanostructure extending between second source/drain regions; and a second cell including a third active region, where the third active region includes a third nanostructure extending between third source/drain regions; and a fourth nanostructure over the third nanostructure, the fourth nanostructure extending between fourth source/drain regions, where a width of the first active region is greater than a width of the third active region. In an embodiment, the semiconductor device further includes a first gate stack around the first nanostructure of the first active region and the first nanostructure of the second active region; and a second gate stack over the first gate stack and disposed around the second nanostructure of the first active region and the second nanostructure of the second active region. In an embodiment, the semiconductor device further includes a third gate stack around the third nanostructure of the third active region; and a fourth gate stack over the third gate stack and disposed around the fourth nanostructure of the third active region. In an embodiment, the semiconductor device further includes an isolation structure extending through the first gate stack and the second gate stack to electrically isolate a first portion of the first gate stack from a second portion of the first gate stack, and a first portion of the second gate stack from a second portion of the second gate stack. In an embodiment, the isolation structure is disposed between the second active region of the first cell and a fourth active region of a third cell. In an embodiment, a width between a first sidewall of the first active region and a first sidewall of the second active region that faces the first sidewall of the first active region is in a range from 5 nm to 30 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first cell comprising a first active region and a second active region adjacent to the first active region, wherein each of the first active region and the second active region comprises:
a first nanostructure extending between first source/drain regions; and
a second nanostructure over the first nanostructure, the second nanostructure extending between second source/drain regions;
a second cell adjacent to the first cell, the second cell comprising a third active region, wherein the third active region comprises:
a third nanostructure extending between third source/drain regions; and
a fourth nanostructure over the third nanostructure, the fourth nanostructure extending between fourth source/drain regions;
a first gate stack around the first nanostructure of the first active region, the first nanostructure of the second active region, and the third nanostructure of the third active region; and
a second gate stack over the first gate stack and disposed around the second nanostructure of the first active region, the second nanostructure of the second active region, and the fourth nanostructure of the third active region.

2. The semiconductor device of claim 1, further comprising:
an isolation structure disposed between the first cell and the second cell, wherein the isolation structure extends through the first gate stack and the second gate stack to electrically isolate a first portion of the first gate stack from a second portion of the first gate stack, and a first portion of the second gate stack from a second portion of the second gate stack.

3. The semiconductor device of claim 2, wherein the isolation structure is disposed between a sidewall of the second active region and a sidewall of the third active region.

4. The semiconductor device of claim 2, wherein the isolation structure comprises silicon oxide or silicon nitride.

5. The semiconductor device of claim 2, wherein the first gate stack comprises a first gate electrode, the second gate stack comprises a second gate electrode, and wherein a material of the first gate electrode is different from a material of the second gate electrode.

6. The semiconductor device of claim 2, further comprising a first gate contact over and electrically coupled to the first portion of the second gate stack, and a second gate contact over and electrically coupled to the second portion of the second gate stack.

7. The semiconductor device of claim 1, wherein the second cell further comprises a fourth active region, wherein the fourth active region comprises:
a fifth nanostructure extending between fifth source/drain regions; and
a sixth nanostructure over the fifth nanostructure, the sixth nanostructure extending between sixth source/drain regions.

8. A semiconductor device comprising:
a first cell comprising a first active region, wherein the first active region comprises:
a first nanostructure extending between first source/drain regions; and
a second nanostructure over the first nanostructure, the second nanostructure extending between second source/drain regions;
a second cell adjacent to the first cell, the second cell comprising a second active region, wherein the second active region comprises:
a third nanostructure extending between third source/drain regions; and
a fourth nanostructure over the third nanostructure, the fourth nanostructure extending between fourth source/drain regions;
a first gate stack around the first nanostructure of the first active region and the third nanostructure of the second active region; and
a second gate stack over the first gate stack and disposed around the second nanostructure of the first active region and the fourth nanostructure of the second active region.

9. The semiconductor device of claim 8, further comprising:
a first isolation structure disposed between the first cell and the second cell, wherein the first isolation structure extends through the first gate stack and the second gate stack to electrically isolate a first portion of the first gate stack from a second portion of the first gate stack, and a first portion of the second gate stack from a second portion of the second gate stack.

10. The semiconductor device of claim 9, wherein the first isolation structure comprises silicon oxide or silicon nitride.

11. The semiconductor device of claim 9, further comprising:
a third cell adjacent to the second cell, the third cell comprising a third active region, wherein the third active region comprises:
a fifth nanostructure extending between fifth source/drain regions; and
a sixth nanostructure over the fifth nanostructure, the sixth nanostructure extending between sixth source/drain regions.

12. The semiconductor device of claim 11, wherein the first gate stack is disposed around the fifth nanostructure of the third active region, and the second gate stack is disposed around the sixth nanostructure of the third active region.

13. The semiconductor device of claim 12, further comprising:
a second isolation structure disposed between the second cell and the third cell, wherein the second isolation structure extends through the first gate stack and the second gate stack to electrically isolate the second portion of the first gate stack from a third portion of the first gate stack, and the second portion of the second gate stack from a third portion of the second gate stack.

14. The semiconductor device of claim 13, further comprising a first gate contact over and electrically coupled to the first portion of the second gate stack, a second gate contact over and electrically coupled to the second portion of the second gate stack, and a third gate contact over and electrically coupled to the third portion of the second gate stack.

15. A method comprising:
forming a first fin structure and a second fin structure that protrude from a substrate, wherein each of the first fin structure and the second fin structure comprises alternating semiconductor nanostructures and dummy nanostructures, wherein each of the first fin structure and the second fin structure comprises a lower semiconductor nanostructure of the semiconductor nanostructures and an upper semiconductor nanostructure of the semiconductor nanostructures disposed over the lower semiconductor nanostructure;
replacing the dummy nanostructures of the first fin structure and the second fin structure with a lower gate stack around the lower semiconductor nanostructure of the first fin structure and the lower semiconductor nanostructure of the second fin structure, and an upper gate stack around the upper semiconductor nanostructure of the first fin structure and the upper semiconductor nanostructure of the second fin structure; and
forming an isolation structure that is disposed between the first fin structure and the second fin structure, wherein the isolation structure extends through the lower gate stack and the upper gate stack, wherein the isolation structure electrically isolates a first portion of the lower gate stack from a second portion of the lower gate stack, and a first portion of the upper gate stack from a second portion of the upper gate stack.

16. The method of claim 15, further comprising:
epitaxially growing lower source/drain regions in each of the first fin structure and the second fin structure; and
epitaxially growing upper source/drain regions over the lower source/drain regions in each of the first fin structure and the second fin structure.

17. The method of claim 15, wherein the lower gate stack is electrically coupled to the upper gate stack.

18. The method of claim 15, wherein the isolation structure comprises silicon oxide or silicon nitride.

19. The method of claim 15, wherein the lower gate stack comprises a first gate electrode, the upper gate stack comprises a second gate electrode, and wherein a material of the first gate electrode is different from a material of the second gate electrode.

20. The method of claim 15, further comprising:
forming a first gate contact over and electrically coupled to the first portion of the upper gate stack, and a second gate contact over and electrically coupled to the second portion of the upper gate stack.
